(19) United States
(12) Patent Application Publication
(10) Pub. No.: US 2021/0391481 A1
(43) Pub. Date: Dec. 16, 2021

(54) Power Semiconductor Device and Shadow-Mask Free Method for Producing Such Device

(71) Applicant: ABB Power Grids Switzerland AG, Baden (CH)

(72) Inventors: Charalampos Papadopoulos, Lenzburg (CH); Boni Kofi Boksteen, Lenzburg (CH); Maxi Andenna, Dättwil (CH); Chiara Corvasce, Bergdietikon (CH); Gerhard Kunkel, Wohlen (CH)

(21) Appl. No.: 17/295,744

(22) PCT Filed: Oct. 17, 2019
(86) PCT No.: PCT/EP2019/078235

§ 371 Date: May 20, 2021

(30) Foreign Application Priority Data
Nov. 20, 2018 (EP) 18207327.0

(51) Int. Cl. H01L 29/861; H01L 29/06; H01L 29/66; H01L 29/78

(52) U.S. Cl. CPC H01L 29/8611; H01L 29/7811; H01L 29/66128; H01L 29/0619

(57) ABSTRACT

A power semiconductor device comprises a wafer (2) having an active region (AR) and a termination region (TR) laterally surrounding the active region; floating field rings in the termination region; a lifetime control region comprising defects reducing a carrier lifetime; and a protecting layer (6) on the wafer. The protecting layer covers the termination region and comprises a thin portion (61) and a thick portion (62) laterally surrounding the thin portion. The thick portion covers the floating field rings. The lifetime control region (5) extends in a lateral direction throughout the active region and in the termination region throughout a portion which is covered by the thin portion and not in a portion which is covered by the thick portion. According to a fabrication method the lifetime control region is formed by irradiating the wafer (2) with ions using the protecting layer (6) as an irradiation mask.

### TECHNICAL BACKGROUND

A power semiconductor device, such as for example a power diode, typically comprises a wafer which comprises an anode layer with p-type conductivity adjacent to one of the main surfaces of the wafer, a base layer with n-type conductivity in direct contact with the anode layer to form a pn-junction, and a cathode layer adjacent to the other main surface of the wafer and having n-type conductivity with a higher doping concentration than the base layer. The anode and cathode layers are typically formed by implantation and a subsequent diffusion of dopants into an n-type semiconductor substrate. On their outer side the cathode layer and the anode layer are covered with metal layers forming electrodes for electrically contacting the semiconductor device. The cathode layer and cathode electrode normally extend to the physical edge of the device. The anode layer, on the other hand, has to be terminated at some distance from the edge in order to be able to support an electric field when reverse biased. Normally, this is done by limiting the p-type anode layer to the central part of the device. The area between the anode electrode and the cathode electrode is normally defined as the active region of the semiconductor device and it is laterally surrounded by a circumferential area which is normally defined as the termination region.

A field-limiting junction termination region may be formed in the termination region, for example in a circumferential portion of the termination region. The junction termination region may comprise a plurality of floating field rings adjacent to the anode side surface of the wafer. Each one of the floating field rings may be a ring-shaped semiconductor region of the p-type, which is laterally surrounding the active region and the anode layer and which forms a second pn-junction with the base layer. The floating field rings are normally spaced from each other in the lateral direction and are separated from each other by the n-type base layer. Floating field rings are sometimes also termed guard rings.

Due to known effects which are e.g. described in EP 1 909 332 A1, a power semiconductor device may require local lifetime control in the active region for optimized electrical properties in blocking, switching and conduction state. Therefore, a lifetime control region may be generated close to the anode side surface of the wafer. This lifetime control region comprises defects forming recombination centers which may locally reduce a minority carrier lifetime. For example, such defects may be generated introducing impurity atoms, usually heavy atoms like gold or platinum into the epi layer by thermal diffusion prior to the realization of the semiconductor device, or by irradiating the anode side surface with high energy electrons or ions like hydrogen ions or helium ions, thereby implanting these ions at a specific depth and thus forming electrically active defects. These local irradiation defects typically reduce the peak voltage generated in the semiconductor device during turn off, also known as reverse recovery peak, and may improve the safe operating area (SOA).

When generating the lifetime control region, due to procedural reasons, the entire anode side surface of the wafer is typically irradiated with such lifetime control region forming ions. However, it has been observed that a portion of the lifetime control region extending into a circumferential portion of the termination region, for example into the junction termination region, may negatively influence electrical characteristics of the semiconductor device.

To prevent or reduce such ion implantation into the circumferential portion of the termination region, this circumferential portion is conventionally covered by a shadow mask. Thereby, the shadow mask should be positioned such as to reproducibly cover and protect the circumferential region of the termination region during an implantation procedure while leaving a central region including the anode layer uncovered such that in this region a lifetime control region may be generated by ion implantation. However, a correct positioning of such shadow mask is difficult and a relatively low aligning accuracy of less than several hundreds of micrometers may be realized. Misalignments of the shadow mask during a production prevent that the circumferential portion of the termination region is properly protected from the irradiation and may negatively influence a safe operating area (SOA) and/or a blocking capability of the semiconductor device. Moreover, a negative effect of the misaligned mask may be worsened when the ion beam is irradiated at an angle to the surface of the wafer, i.e. tilted with respect to the surface normal, as it is the case in conventional irradiation facilities.

To improve on this, it is known from EP 2 339 613 A1 the idea to provide a spacer region between the anode layer and the junction termination region, spacing apart and electrically separating the active area of the diode from the junction termination region.

When the width of the spacer region is sufficiently large, accurate alignment of the shadow mask during an ion implantation becomes less problematic and implanting lifetime control region generating ions into the circumferential portion of the termination region may be prevented. However, having such a spacer region will result in an increased size of the termination region and thus less active area per chip. Moreover, in particular when using metallic shadow masks, there is some risk of mechanically damaging the underlying surface when positioning the shadow mask before implantation or removing the shadow mask after implantation, with negative effects on the performance.

From prior art document US 2012/0032305 A1 it is known a semiconductor device and a manufacturing method thereof in which the semiconductor device includes a p-type anode layer formed by a transition metal acceptor transition, and the manufacturing process is simplified without deteriorating the breakdown voltage characteristics. An inversion advancement region inverted to a p-type by a transition metal acceptor transition, and in which the acceptor transition is advanced by point defect layers, is formed on the upper surface of an n-type drift layer. The inversion advancement region configures a p-type anode layer of a semiconductor device of the invention. The transition metal is, for example, platinum or gold. An n-type semiconductor substrate with a concentration higher than that of the n-type drift layer is adjacent to the lower surface of the n-type drift layer.

From prior art document US 2014/0070369 A1 it is known a manufacturing process that stably produces a semiconductor device with high electrical characteristics, wherein platinum acts as an acceptor. Plasma treatment damages the surface of an oxide film formed on an n⁻ type drift layer deposited on an n⁺ type semiconductor substrate. The oxide film is patterned to have tapered ends. Two proton irradiations are carried out on the n⁻ type drift layer with the oxide film as a mask to form a point defect region in the vicinity of the surface of the n⁻ type drift layer. Silica paste containing 1% by weight platinum is applied to an exposed region of the n⁻ type drift layer surface not covered with the oxide film. Heat treatment inverts the vicinity of the surface of the n⁻ type drift layer to p-type by platinum atoms which are acceptors. A p-type inversion enhancement region forms a p-type anode region.

### SUMMARY OF THE INVENTION

In view of the above it is an object of the present invention to provide a power semiconductor device having improved electrical characteristics and a shadow-mask free method for producing such device. Particularly, it is an object of the present invention to provide a power semiconductor device such as a power diode having improved electrical blocking capability while at the same time providing satisfying switch-off characteristics.

The object of the invention is attained by a power semiconductor device according to claim 1 and a method of fabricating such a power semiconductor device according to claim 11.

A power semiconductor device according to the invention comprises a wafer which has a first main side surface and a second main side surface opposite to the first main side surface. The first main side surface and the second main side surface extend in a lateral direction. The wafer comprises an active region and a termination region laterally surrounding the active region, a plurality of floating field rings in the termination region adjacent to the first main side surface, and in the order from the first main side surface to the second main side surface a first semiconductor layer of a first conductivity type, for example a n-type or a p-type conductivity, and a second semiconductor layer of a second conductivity type which is different from the first conductivity type. The second semiconductor layer is in direct contact with the first semiconductor layer to form a first pn-junction. Each one of the floating field rings is a ring-shaped semiconductor region of the first conductivity type, which laterally surrounds the active region and the first semiconductor layer and which forms a second pn-junction with the second semiconductor layer, and the floating field rings are spaced from each other in the lateral direction and are separated from each other by the second semiconductor layer. A first electrode on the first main side surface forms a first contact with the first semiconductor layer and a second electrode on the second main side surface forms a second contact. Furthermore, a protecting layer is arranged on the first main side surface and the protecting layer covers the termination region. The protecting layer covering the termination region comprises a thin portion and a thick portion laterally surrounding the thin portion. The thick portion has an inner end and an outer end laterally surrounding the inner end. The thick portion has a minimal thickness which is larger than a maximal thickness of the thin portion. The plurality of floating field rings is formed below the thick portion of the protecting layer. The power semiconductor device further comprises a lifetime control region comprising defects which reduce a carrier lifetime. The lifetime control region extends in the lateral direction throughout the active region, and throughout a portion of the termination region which is covered by the thin portion of the protecting layer. The lifetime control region does not extend in a portion of the termination region covered by the thick portion of the protecting layer.

A method for fabricating the power semiconductor device according to the invention comprises a step of providing a wafer which has a first main side surface and a second main side surface opposite to the first main side surface and which extend in a lateral direction. The wafer comprises an active region and a termination region laterally surrounding the active region, and in the order from the first main side surface to the second main side surface a first semiconductor layer of a first conductivity type and a second semiconductor layer of a second conductivity type which is different from the first conductivity type. The second semiconductor layer is in direct contact with the first semiconductor layer to form a first pn-junction. The method further comprises a step of forming a first electrode on the first main side surface to form a first contact with the first semiconductor layer, and a step of forming a second electrode on the second main side surface to form a second contact. Furthermore the method comprises a step of forming the protecting layer on the first main side surface such that the protecting layer covers the termination region and comprises in the termination region a thin portion and a thick portion laterally surrounding the thin portion. The thick portion has an inner end and an outer end laterally surrounding the inner end. The thick portion has a minimal thickness which is larger than a maximal thickness of the thin portion. After the step of forming the protecting layer, the method comprises a step of forming a lifetime control region in the wafer by irradiating the wafer with ions using the protecting layer as an irradiation mask, thereby forming defects reducing a carrier lifetime at a predetermined depth in the active region and in a portion of the termination region which is covered by the thin portion, and not in a portion of the termination region which is covered by the thick portion of the protecting layer at the predetermined depth.

According to an aspect of the invention the protecting layer is used as an irradiation mask in the step of forming the lifetime control region, the mask allowing the implantation of ions in some areas of the wafer while preventing or reducing implantation of ions into other areas of the wafer. In particular, the protecting layer prevents or reduces the implantation of ions into an outer circumferential portion of the termination region where the thick portion of the protecting layer is formed, and allows the implantation of more ions into a portion of the termination region where the thin portion of the protecting layer is formed. Moreover, because alignment of the protecting layer relative to the wafer can be done with higher precision than alignment of a shadow mask, a high implantation accuracy can be achieved, resulting in a more precise control of the position of the lifetime control region. This may enable, for example, to generate a lifetime control region laterally extending throughout the active region and into a first portion of the termination region comprising the first semiconductor layer, but not extending into a circumferential portion of the termination region, where implantation of ions is not desired. A spacer region may therefore not be required or may be significantly reduced in size, thus leading to a device with a smaller termination region. Overall, a device with optimized electrical characteristics may be achieved.

According to another aspect of the invention, the protecting layer protects the wafer from moisture, mechanical damage and/or pollution. For example, by forming the protecting layer in an early fabrication step, e.g. prior to an ion implantation step, and by not removing the protecting layer after the implantation step (in contrast to what is done in prior art when using a shadow mask), the risk of polluting and/or damaging the wafer is reduced. Moreover, the protecting layer keeps polluting particles at a distance from the electric field such that an interference between polluting particles and the electric field may be prevented.

Overall, a semiconductor device according to claim 1 provides the advantage that the protecting layer covering the (entire) termination region can simultaneously serve as an irradiation mask for ion implantation for generation of a lifetime control region and as protective layer for the termination region. The ingenious protecting layer thus allows a less complex (since no shadow mask is used) and cheaper as well as more precise production of the lifetime control region and by a precise lifetime control region improved electrical characteristics.

Further developments of the invention are specified in the dependent claims.

In an exemplary embodiment the minimal thickness of the thick portion is at least double the maximal thickness of the thin portion.

In an exemplary embodiment the minimal thickness of the thick portion is at least 10 μm/α, or at least 12 μm/α, or at least 15 μm/α, and the maximal thickness of the thin portion is less than 5 μm/α, or between 1 μm /α and 5 μm/α. α is a factor between 1 and 3. α depends on the material of the protecting layer and its screening properties. For example, for a polymer, e.g. polyimide or polybenzoxazol (PBO), a may be 1; for an oxide a may be 1.6, and for a nitride a may be 2.4.

In an exemplary embodiment, at a predetermined depth below the first main surface in a portion of the termination region which is covered by the thin portion of the protecting layer, a concentration of defects reducing a carrier lifetime is at least thousand times, or exemplarily at least a million times a concentration of such defects in a portion of the termination region which is covered by the thick portion of the protecting layer at the predetermined depth. For example, a concentration of such defects at a predetermined depth in the termination region below the thick portion of the protecting layer may be substantially zero, whereas there is a significant amount of such defects (i.e. at least a million times higher concentration) at the predetermined depth in the termination region below the thin portion of the protecting layer. In all of these cases, it may be understood, that the lifetime control region does not extend in a portion of the termination region covered by the thick portion of the protecting layer.

In an exemplary embodiment, implanted defects are located adjacent to the first pn-junction formed between the first semiconductor layer and second semiconductor layer. This may give an improved trade-off between voltage drop in an on-state of the semiconductor device and reverse recovery energy losses during switching.

In an exemplary embodiment, the inner end of the thick portion has at least the same distance in a lateral direction from a circumferential end of the first electrode as a circumferential end of the first semiconductor layer from the circumferential end of the first electrode. This may provide improved performance of the semiconductor device.

In an exemplary embodiment, the inner end of the thick portion forms an edge between a side facing towards the active region AR and a side opposite to the wafer. The edge may for example be a rounded edge or a substantially straight edge. The edge may for example have a rounded corner or a sharp corner. The edge may for example be inclined with respect to the surface normal of the first main surface or may be a substantially vertical edge, i.e. an edge substantially parallel to the surface normal of the first main surface. A substantially vertical edge may be particularly beneficial by providing the ability to form a life-time control region which ends in a lateral direction at a precise position.

In an exemplary embodiment, the lifetime control region and/or adjacent semiconductor material comprise hydrogen ions or helium ions or other inert gas ions. For example, the hydrogen ions, helium ions or other inert gas ions may form the lifetime reducing defects. Lifetime reducing defects may be generated by irradiation of the wafer with helium ions or hydrogen ions or other inert gas ions or high energy electrons. Using helium ions or hydrogen ions or other inert gas ions may provide the ability to reduce the lifetime only in a limited thickness of the wafer, because the recombination centers are mostly generated at the depth where the ions are stopped, and the position of the lifetime decrease may be modified by changing the energy of the irradiated ions. A minimum lifetime point is where the ions stop in the material.

In an exemplary embodiment, a circumferential portion of the first semiconductor layer forms a junction termination extension (JTE). The JTE may comprise a plurality of partially overlapping JTE rings comprising low-doped p-type semiconductor material. The JTE may help to decrease the electric field on the outer edge of the main junction by distributing the potential along the width of the JTE.

In an exemplary embodiment, the protecting layer comprises helium at a concentration which is higher than a concentration of helium impurities naturally present in a material forming the protecting layer. In particular, the thin portion of the protecting layer may comprise a lower concentration of helium than the thick portion of the protecting layer at a same distance from the first main surface of the wafer. For example, at the same distance from the first main surface of the wafer, a concentration of helium atoms in the thick portion of the protecting layer may be at least ten times, or exemplarily at least thousand times, higher than a concentration of helium atoms in the thin portion of the protecting layer.

In exemplarily embodiment, the protecting layer comprises a polymer material, for example polyimide or polybenzoxazole (PBO). In such an embodiment, a maximal thickness of the thin portion may for example be in a range between 1 μm and 5 μm and a minimal thickness of the thick portion may for example be at least 10 μm, for example at least 12 μm or at least 15 μm.

In another exemplary embodiment, the protecting layer is a passivation layer and comprises a dielectric material such as an oxide or a nitride. In such an embodiment, a maximal thickness of the thin portion may for example be less than 3 μm and a minimal thickness of the thick portion may for example be at least 5 μm.

According to an exemplary embodiment the protecting layer covers the entire termination region.

In an exemplary embodiment, the step for forming the protecting layer comprises a step of forming a first protecting layer with a first thickness covering an outer portion of the termination region and a step of forming a second protecting layer with a second thickness on the first protecting layer also covering the outer portion of the termination region. Thereby, one of the first protecting layer and the second protecting layer is formed such that it also covers at least an inner portion of the termination region which is adjacent to the outer portion and the other of the first protecting layer and the second protecting layer does not cover the inner portion. The protecting layer is formed by the first protecting layer and the second protecting layer. For example, the first protecting layer may be a thin layer covering both an inner and the outer portion of the termination region, i.e. it may cover the entire termination region, and the second protecting layer may be a thick layer only formed on an outer portion of the first layer covering the outer portion of the termination region but not covering the inner portion of the termination region. The thickness of the first protecting layer (first thickness) may correspond to a thickness of the thin portion of the protecting layer and a combined thickness (first thickness plus second thickness) of the first protecting layer and the second protecting layer may correspond to a thickness of the thick portion of the protecting layer. This approach may yield an inner end of the thick portion which has a substantially straight edge with a sharp corer. Alternatively, the first protecting layer may be a thick layer covering only the outer portion of the termination region and the second protecting layer may be a thin layer covering both the first protecting layer and an inner portion of the termination region TR. This approach may yield an inner end of the thick portion which has an edge with a more rounded corner.

In a different exemplary embodiment, the step for forming the protecting layer comprises a step of forming a uniform protecting layer covering the entire termination region, a step of providing a mask on the protecting layer, a step of exposing the protecting layer through the mask, wherein the mask is configured to expose an outer portion of the uniform protecting layer to a different amount of light than an inner portion of the uniform protecting layer, and a step of chemically removing at least a portion of an inner portion of the uniform protecting layer, thereby forming the protecting layer comprising the first and the second protecting layer.

In an exemplary embodiment, the step of forming the lifetime control region is performed after the step of forming the first electrode.

Throughout this application, when the expression “substantially” is applied to a structural or technical feature, then this means that this feature is present within the technical tolerance of the method used to manufacture it. Moreover, a “lateral” direction is a direction perpendicular to the surface normal of the first main surface. In the lateral direction, an “outer portion” of a region is closer to a circumferential end of the region than an “inner portion” of the region is to the circumferential end of the region. A thickness of a layer refers to the distance between an upper and a lower surface of the layer. A “circumferential portion” of the termination region is a portion of the termination region which is closer in the lateral direction to a circumferential end of the wafer than a central portion of the wafer is to the circumferential end of the wafer. A “circumferential portion” is an outer portion.

### BRIEF DESCRIPTION OF THE DRAWINGS

Embodiments of the invention will be explained in more detail in the following text with reference to the attached drawings in which:

FIG. 1 shows a cross-sectional view of a power diode illustrating some aspects of the invention.

FIG. 2 shows a partial cross-sectional view of a power diode according to an embodiment of the invention.

FIG. 3 shows a partial cross-sectional view of a power diode according to an embodiment of the invention.

FIG. 4A-D illustrate method steps for forming a power diode according to an embodiment of the invention.

The reference signs used in the figures and their meanings are summarized in the list of reference signs. Generally, similar elements have the same reference signs throughout the specification. The drawings are only schematically and not to scale. Due to visibility reasons, similar elements which are repeating themselves in a figure are only labeled once. The described embodiments are meant as examples and shall not limit the scope of the invention.

### DETAILED DESCRIPTION OF THE EMBODIMENTS

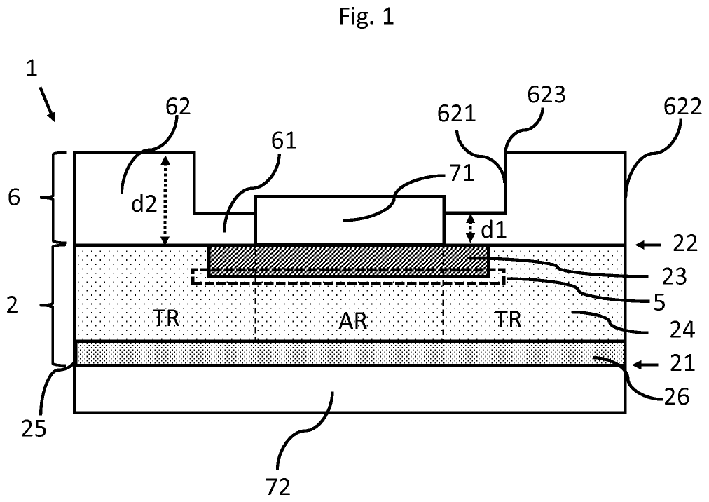

FIG. 1 shows a cross-section of a power semiconductor device 1 illustrating aspects of the present invention. The semiconductor device 1 is a power diode.

The power diode comprises a semiconductor wafer 2 made of silicon (Si). The semiconductor wafer 2 has a first main side surface 22 and a second main side surface 21 opposite to the first main side surface 22. The first main side surface 22 and the second main side surface 21 extend in a lateral direction. In the order from the first main side surface 22 to the second main side surface 21 the semiconductor wafer 2 has a p-doped anode layer 23, a n-doped drift layer 24 and a highly doped n⁺-substrate layer 26 having a doping concentration higher than the n-doped drift layer 24. The p-doped anode layer 23 may for example be a highly doped p⁺-anode layer. The p-doped anode layer 23 is a first semiconductor layer 23, the n-doped drift layer 24 is a second semiconductor layer 24, and the n⁺-substrate layer 26 is a third semiconductor layer 26. Appropriate doping concentrations of the individual layers and their thicknesses are known in the art. On the second main side surface 21 of the semiconductor wafer 2 there is formed a back metallization layer 72 as a cathode electrode (second electrode) 72 which forms an ohmic contact with the highly-doped n⁺-substrate layer 26. A top metallization layer 71 is formed on the first main side surface 22 as an anode electrode (first electrode) 71 forming an ohmic contact with the p-doped anode layer 23. The n⁺ substrate layer 26 and the cathode electrode 72 extend to a circumferential end 25 of the semiconductor wafer 2. The p-doped anode layer 23 ends at some distance from the circumferential end 25 of the semiconductor wafer 2. The anode electrode 71 is arranged on a central portion of the semiconductor wafer 2. The anode electrode 71 is arranged on a central portion of the p-doped anode layer 23. A circumferential end of the anode electrode 71 ends at some distance of a circumferential end of the p-doped anode layer 23. Moreover, the semiconductor wafer 2 comprises an active region AR between the anode electrode 71 and the cathode electrode 72 and a termination region TR which is laterally surrounding the active region AR. A circumferential end of the p-doped anode layer 23 extends into the termination region TR. On the first main side surface 22 of the semiconductor wafer 2 there is formed a protecting layer 6. The protecting layer 6 is exemplarily made of a polymer material, e.g. polyimide and/or polybenzoxazole (PBO). The protecting layer 6 covers the entire termination region TR of the semiconductor wafer 2. The protecting layer 6 comprises a thin portion 61 and a thick portion 62 laterally surrounding the thin portion 61. The thick portion 62 has an inner end 621 and an outer end 622 laterally surrounding the inner end 621. The thick portion 62 exemplarily has a minimal thickness d2 of 15 μm. The thin portion 61 exemplarily has a maximal thickness d1 of 5 μm. The thickness dl of the thin portion 61 and the thickness d2 of the thick portion 62 may vary depending of the material of the protecting layer 6 and the desired implantation depth. A maximal thickness d2 of the thin portion 61 may for example be between 1 μm and 5 μm.

A minimal thickness d1 of the thick portion may for example be at least 10 μm. A maximal thickness d2 of the thick portion may for example be 30 μm. The inner end 621 of the thick portion 62 forms an edge between a side facing towards the active region AR and a side opposite to the wafer 2. The edge is a substantially straight edge and has a sharp corner 623. The edge (inner end 621) of the thick portion 62 is more distant in a lateral direction from a circumferential end of the first electrode 71 than a circumferential end of the first semiconductor layer 23 is from the circumferential end of the first electrode 71. The edge (inner end 621) may however be substantially aligned with the circumferential end of the first semiconductor layer 23.

The semiconductor device 1 further comprises a lifetime control region 5 comprising defects which reduce a carrier lifetime. The lifetime control region 5 extends in the lateral direction throughout the active region AR and in a portion of the termination region TR covered by the thin portion 61 of the protecting layer 6. The lifetime control region 5 does not extent into a portion of the termination region TR covered by the thick portion 62 of the protecting layer 6. In this example, the lifetime control region 5 is formed at a depth approximately corresponding to the depth at which the first pn-junction is formed, but may also be formed substantially closer to the main side surface 22. For example, the depth at which the lifetime control region 5 is formed may be between 1 μm and 15 μm. However, deeper depths are not excluded. For instance, in bipolar diodes the lifetime control region 5 may extent in a depth between 1 μm and 200 μm. The defects forming the lifetime control region 5 comprise for example helium or hydrogen or other inert gas atoms. At a predetermined depth beyond the first main surface 22, for example at a depth of 8 μm, a number of such defect forming ions is substantially zero in a portion of the termination region TR covered by the thick portion 62 of the protecting layer 6, whereas at the same depth there is a substantial amount of defect forming ions in a portion of the termination region TR which is covered by the thin portion 61 of the protecting layer 6. Thus, at a predetermined depth, a concentration of defect forming ions in the lifetime control region 5 is at least thousand times, or exemplarily at least a million times a concentration of defect forming ions in the circumferential portion of the termination region TR that is below the thick portion 62 of the protecting layer 6 at the predetermined depth. Moreover, the protecting layer 6 may comprise helium atoms. At a predetermined distance from the first main side surface 22, a concentration of helium in the thick portion 62 of the protecting layer 6 is at least ten times, or exemplarily at least a thousand times a concentration of helium in the thin portion 61 of the protecting layer 6 at the predetermined distance.

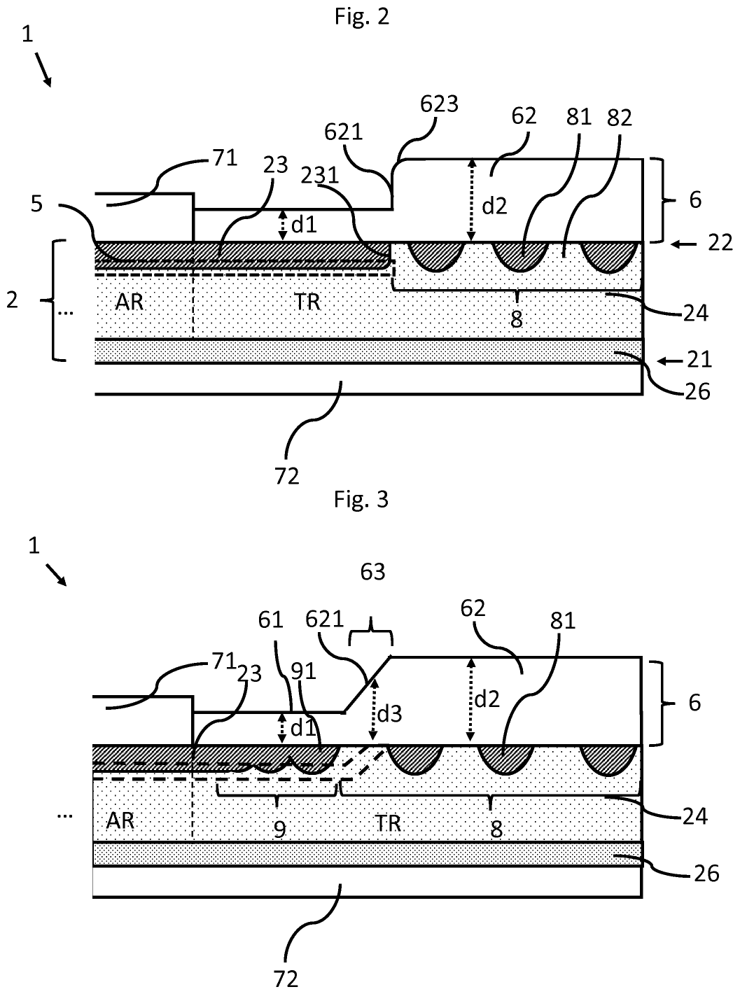

FIG. 2 shows a partial cross-sectional view of a power diode 1 according to an embodiment of the invention. A part of the power diode 1 which is not shown may be mirror symmetric to the part shown in FIG. 2. Due to the many similarities between this embodiment and the embodiment shown in FIG. 1, only differences are described. Other features are essentially the same as described above with respect to FIG. 1 and reference is made to the description above. The embodiment shown in FIG. 2 comprises a plurality of floating field rings (guard rings) 81 in a circumferential portion of the termination region TR adjacent to the first main side surface 22 of the semiconductor wafer 2. The purpose of the floating field rings 81 in circumferential portion of the termination region TR is to alleviate the field crowding effect at the outer edges of the device main junction by allowing the depletion region to extend through consecutively lower biased floating junctions. Each one of the floating field rings 81 is a ring-shaped semiconductor region of p-type conductivity, for example highly-doped p⁺-type conductivity. The plurality of floating field rings 81 is laterally surrounding the active region AR and the p-type anode layer 23. The plurality of floating field rings 81 form a field limiting termination junction region 8. The individual field rings 81 are self-contained regions. In a top view, i.e. in an orthogonal projection onto a plane parallels to the first main side, these regions are formed as rings (e.g. annuli, squares or any other appropriate design). The floating field rings 81 are in direct contact with the first main side surface 22 of the wafer 2. That means that there is no gap nor any other semiconductor layer formed between the floating field rings 81 and the first wafer main side surface 2. Moreover, the floating field rings 81 are spaced from each other in the lateral direction with a distance between each pair of neighboring floating field rings 81 in the lateral direction is exemplarily in a range from 5 μm to 200 μm. The width of the floating field rings 25 in the lateral direction may be up to 100 μm. The width of the field rings may be reduced as much as possible to save space. The depth of the field rings to which they extend from the first main side surface 22 may be the same as the depth of p-type anode layer 23. The doping concentration of the floating field rings 81 may exemplarily be 1·10¹⁵ cm⁻³ or higher. The floating field rings 81 are formed in the n-type drift layer 24 so that each of them is in direct contact with the n-type drift layer 24, thus form a pn-junction (second pn-junction in the claims). The plurality of field rings 81 is arranged below the thick portion 62 of the protecting layer 6. The inner end 621 of the protecting layer 6 forms a substantially vertical edge with a rounded corner 623. A circumferential end 231 of the p-type anode layer 23 is aligned in the lateral direction with the inner end 621 of the thick portion 620 of the protecting layer 6. A lifetime control region 5 is formed in the semiconductor wafer 2. The lifetime control region 5 extends in the lateral direction throughout the active region AR into the termination region TR to the inner end 621 of the thick portion 62, i.e. the projection of the inner end 621 into the termination region TR.

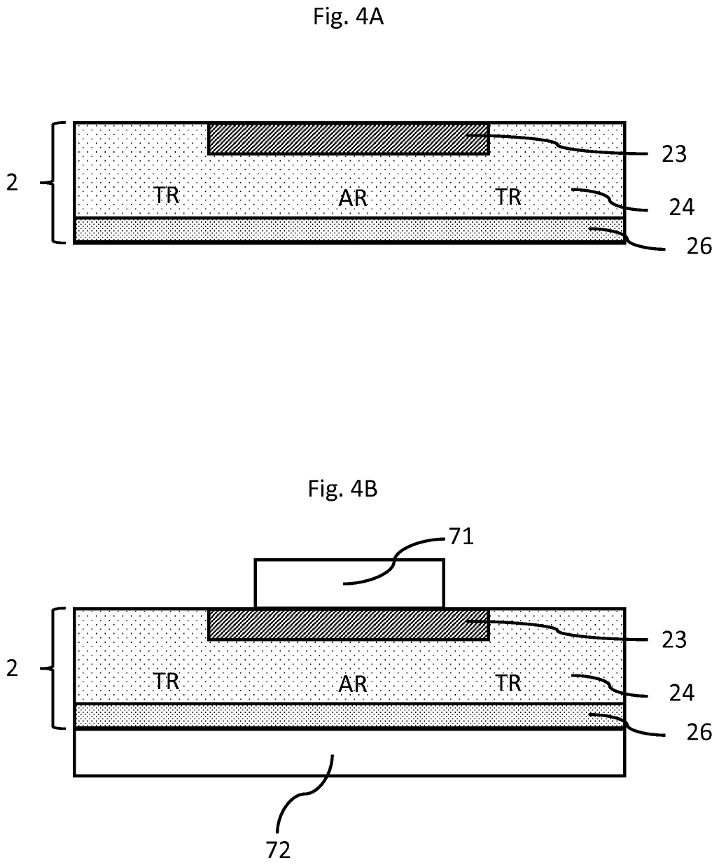

FIG. 3 shows a partial cross-sectional view of a power diode 1 according to an exemplary embodiment of the invention. Due to many similarities between this embodiment and the embodiments described with respect to FIGS. 1 and 2, only differences are described and reference is made to the description above. The power diode 1 shown in FIG. 3 uses an additional junction termination extension (JTE) 9. The JTE 9 has p-type conductivity. The JTE 9 is adjacent to the first main surface 22 and in direct contact with the p-type anode layer 23. The JTE 9 is formed by a plurality of partially overlapping JTE rings 91. The degree of overlap decreases in the circumferential direction. JTE rings 91 are low-doped p⁻-ring-shaped semiconductor regions laterally surrounding the active region AR and the p-type anode layer 23. The JTE 9 is formed in a circumferential portion of the first semiconductor layer 23. The JTE regions 91 have a doping concentration which is 1·10¹⁸ cm⁻³ or lower, exemplarily in a range between 1·10¹⁵ cm⁻³ and 8·10¹⁷ cm⁻³. Moreover, the device of the exemplary embodiment comprises a plurality of floating field rings 81 laterally surrounding the first semiconductor layer 23 as described above with respect to FIG. 2. There is no direct contact between a circumferential end of the JTE 9 and the plurality of the field rings 81. The JTE 9 is formed in the termination region TR below a thin portion 61 of the protecting layer 6. The plurality of field rings 81 is formed in the termination region TR below the thick portion 62 of the protecting layer 6. At the inner end 621 of the thick portion 62 of the protecting layer 6 an edge is formed which is inclined with respect to the surface normal of the first main surface 22. Thus, the protecting layer 6 comprises an intermediate portion 63 where its thickness increases continuously. The intermediate portion 63 of the protecting layer 6 is a portion between the thin portion 61 and the thick portion 62, in which the thickness d3 of the protecting layer 6 is more than the thickness dl of the thin portion 61 and less than the thickness d2 of the thick portion 62. A lifetime control region 5 is formed in the semiconductor wafer 2. The lifetime control region 5 extends in the lateral direction throughout the active region AR into the termination region TR. The lifetime control region 5 extends in the lateral direction to a portion of the termination region TR that includes the JTE 9 but does not or only to a small amount extend into a circumferential portion of the termination region TR which includes the plurality of field rings 81. A depth at which ions forming the lifetime control region 5 are located is inverse to a thickness of the thin portion 61. That is, the greater the thickness of the thin portion 61, the less deep the ions are located in the semiconductor wafer 2. Below the thin portion 61 of the protecting layer 6, the ions are located at a depth which corresponds approximately to a depth at which the first pn-junction is formed. Below the intermediate portion 63 of the protecting layer 6, the ions are located at a more shallower depth than below the thick portion 62, and below the thick portion 62 the ions are located in a more shallow depth than below the intermediate region 63 or cannot be found at all.

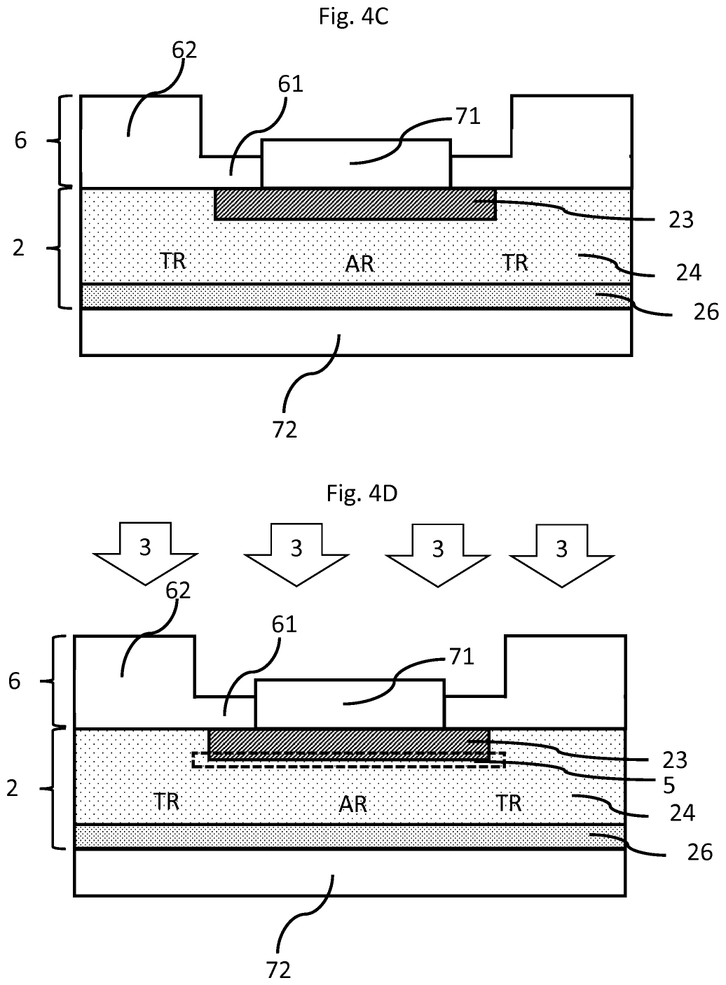

In the following, aspects of a method for manufacturing a power semiconductor device according to the invention are described with reference to FIGS. 4A to 4D. Therein, the abovementioned plurality of the floating field rings 81 comprised in the wafer 2 is omitted for reasons of visibility. The method comprises the following steps:

a) Providing a semiconductor wafer 2 (see FIG. 4A).

b) Forming an anode electrode 71 on the first main side surface 22 and a cathode electrode 72 on the second main side surface 21 according to one of the embodiments described above (see FIG. 4B)

c) Forming a protecting layer 6 on the first main side surface 22 which covers the termination region TR and comprises a thin portion 61 and a thick portion 62 according to one of the embodiments described above (see FIG. 4C).

d) Forming a lifetime control region 5 in the semiconductor wafer 2 by irradiating onto the protecting layer 6 with ions, thereby forming defects reducing the carrier lifetime in the active region AR and an inner portion of the termination region TR.

Referring to steps a) and b), details of the semiconductor wafer 2 and the anode electrode 71 and cathode electrode 72 are described above with respect to FIGS. 1 to 3 and not repeated here for the sake of conciseness. Instead reference is made to the above description. Further, it is known known to the skilled person how to fabricate a semiconductor wafer 2 and electrodes 71, 72 according to the above mentioned embodiments.

Referring to step c), the protecting layer 6 may for example be formed by photolithography or screen printing. A uniform protecting layer is formed on the first main side surface 22 by spin coating and prebaking to drive off excess solvent. For example, the uniform protecting layer may be a uniform polymer layer comprising a photosensitive polymer. Then the uniform protecting layer is exposed to a pattern of intense light using a structured photomask configured to expose an outer portion of the uniform protecting layer, i.e. the portion corresponding to the thick portion 62, to a different amount of light than an inner portion of the uniform protecting layer, i.e. the portion corresponding to the thin portion 61. Then, depending on whether the uniform protecting layer is positive photosensitive or negative photosensitive, the exposed portion (or the unexposed portion) is chemically removed using a developer. After that, the remaining protecting layer may be baked to form a durable protecting layer 6.

A protecting layer 6 according to the above described embodiments may also be formed, for example, by forming on the first main side surface 22 of the semiconductor wafer 2 a uniform first layer with a first thickness covering the entire termination region TR and then forming with the same material than the first uniform layer a uniform second layer with a second thickness on an outer portion of the first layer such that the second layer only covers the outer portion of the termination region TR where the thick portion 62 is to be formed, but does not cover the inner portion of the termination region TR where the thin portion 61 is to be formed. The first thickness may correspond to the thickness (d1) of the thin portion 61 and the second thickness may correspond to the difference between the thickness of the thick portion 62 and the thickness of the thin portion 61, i.e. d2−d1.

Alternatively, a uniform first layer with a first thickness may be formed on the first main side surface 22 of the semiconductor wafer 2 such that it only covers an outer portion of the termination region TR an then a second layer with a second thickness may be formed with the same material than the first layer on the first uniform layer and the remaining portion of the first main side surface 22 such that the entire termination region TR is covered by the second uniform layer. The portion where both the first layer and the second layer are superposed may correspond to the thick portion 62 of the protecting layer 6. The portion where only the second layer covers the termination region TR may correspond to the thin portion 61. With this approach the irradiation step (step d)) may be performed between the formation of the first layer and the formation of the second layer, or alternatively after the formation of both layers. The second approach may be beneficial with respect to preventing moisture issues or pollution of the semiconductor wafer 2.

Referring to step d), the lifetime control region 5 may be formed by implanting defects into the semiconductor wafer 2 by irradiating 3 onto the protecting layer 6 with ions, for example helium ions or hydrogen ions. Since the protecting layer 6 has an outer portion 62 which is thick and an inner portion 61 which is thin, the ion beam 3 is strongly attenuated in the outer portion 62 and only weakly attenuated in the inner portion 61, such that ions passing through the outer portion 62 penetrate not or only very shallow below the first main side surface 22 of the semiconductor wafer 2, whereas ions passing through the inner portion 61 penetrate much deeper into the semiconductor wafer 2. Thus the implantation is substantially restricted to the active region AR and the inner portion of the termination region TR corresponding to the thin portion. For example, for implanting hydrogen ions, implantation energies are typically in a range between 0.5 MeV and 5 MeV and implantation doses are typically in a range between 1·10¹¹ cm⁻² and 1·10¹⁴ cm⁻². For implanting helium ions, implantation energies are typically in a range between 1 MeV and 10 MeV and implantation doses are typically in a range between 1·10¹¹ cm⁻² and 1·10¹³ cm⁻³. With increasing mass of the implanted ion the required irradiation dose decreases.

It will be apparent for persons skilled in the art that modifications of the above described embodiments are possible without departing from the scope of the invention as defined by the appended claims. It has also to be noted that aspects and embodiments of the present invention are described herein with reference to different subject-matters. In particular, some features are described with reference to the method for producing the semiconductor device whereas other features are described with reference to the semiconductor device itself. However, a person skilled in the art will gather from the above that, unless other notified, in addition to any combination or features belonging to one type of subject-matter also any combination between features relating to different subject-matters, in particular between features of semiconductor device and features of the method for producing such device, is considered to be disclosed with this application.

For example, in each of the embodiments described above the thick portion 62 of the protecting layer 6 may have an in inner end 621 forming a substantially vertical edge or an inclined edge, or may have a corner 623 which is a sharp corner or which is a rounded corner.

In the above embodiments the number of the floating field rings 81 is always shown to be three. However, depending on the nominal (maximum) voltage of the device, any number of floating field rings 81 between two and 50 may be used. The higher the nominal voltage of the device the higher is the required number of floating field rings 81 and the number of required JTE rings.

In the above described embodiments the widths of the individual field rings 81 and the distances between two adjacent field rings 81 are the same. However, the widths and distances may also vary. In another preferred embodiment, the width of the floating field rings 81 increases from the innermost floating field ring to the outermost floating field ring 81 stepwise or continuously.

In the above described embodiment the JTE 9 is described as being formed by a plurality of partially overlapping JTE rings 91, wherein the overlap decreases in the circumferential direction. However, the JTE may also be a single JTE ring or the overlap of the JTE rings may not be decreasing in a direction towards a circumferential end.

In the above described embodiments the anode layer 23, the JTE rings 91 and the floating field rings 81 may all have the same doping concentration and may all have the same depth, so that they may can be manufactured in the same implantation process step using only one mask thus facilitating manufacturing. However the anode layer 23, JTE rings 91 and the floating field rings 81 may also have different doping concentrations and may extent to different depths.

In the above described embodiments silicon is used as a semiconductor material. However, it is also possible to implement the high power semiconductor device of the invention also with other semiconductor materials, e.g. with silicon carbide (SiC), a group-III-nitride such as gallium nitride (GaN) or aluminium gallium nitride (AlGaInN), diamond etc.

In the above described embodiments, the field limiting junction termination comprises a plurality of floating field rings 81. However, the field limiting junction termination 8 may also be a variation lateral doping (VAD) region. Moreover, a junction termination extension 9 may also be variation lateral doping (VAD) region.

In the above described embodiments the power semiconductor device 1 is a PiN diode. However the power semiconductor device of the invention may be another high power semiconductor device such as a unipolar diode, a JBS diode, a junction gate field-effect transistor (JFET), a metal-oxide-semiconductor field-effect transistor (MOSFET), an insulated gate bipolar transistor (IGBT), a bipolar junction transistor (BJT), or a thyristor.

In the above described embodiments, it is described that a circumferential end of the anode electrode 71 is distant from a circumferential end of the first semiconductor layer 23 in the lateral direction. However, a circumferential end of the anode electrode 71 may also be substantially aligned with a circumferential end of the semiconductor layer 23 in the lateral direction.

In the figures accompanying the above description of embodiments and methods no passivation layer is shown. However, a passivation layer may be disposed between the first main side surface 22 and the protecting layer 6. The passivation layer may cover both the termination region TR and a portion of the active region AR. The passivation layer can be a non-conductive silicon oxide or silicon nitride layer or a high-k dielectric layer or can be a passivation layer stack comprising plural layers of different dielectrics, for example.

In an exemplarily embodiment, the passivation layer is the protecting layer 6.

In the figures accompanying the above description of embodiments the protecting layer 6 does not cover the anode electrode 71. However the protecting layer 6 may also cover a portion of the anode electrode 71.

In the above described embodiment it is exemplarily described that the ions forming the lifetime control region 5 are implemented at a depth which corresponds to the depth at which the first pn-junction is formed. However, the ions forming the lifetime control region 5 may also be implanted at other depths. Then, the thickness of the protecting layer 6 may have to be adjusted. Moreover, in an exemplary embodiment the thick portion 62 of the protecting layer 6 is sufficiently thick to prevent the irradiated ions from entering a circumferential portion of the termination region TR. However, in some embodiments it may be permissible that a small amount of ions enter the circumferential portion of the termination region TR.

In the above described embodiments, the thickness d1 of the thin portion 61 is substantially constant in the lateral direction and the thickness d2 of the thick portion 62 is substantially constant in the lateral direction. As a result, the defect density in the corresponding portions of the termination region TR is about constant. However, the thickness of the thin portion 61 and/or the thickness of the thick portion 62 may also vary in a lateral direction such that a variation in lateral doping (VLD) region is formed.

The above embodiments are explained with specific conductivity types. The conductivity types of the semiconductor layers in the above described embodiments might be switched, so that all layers which were described as p-type layers would be n-type layers and all layers which were described as n-type layers would be p-type layers.

In the claims, when a region is referred to as adjacent the first main side surface the region can be either in direct contact to the first main side surface or it can be near to the first main side surface at a distant to the first main side surface. It should also be noted that the term “comprising” does not exclude other elements or steps and that the indefinite article “a” or “an” does not exclude the plural. Also elements described in association with different embodiments may be combined.

### LIST OF REFERENCE SIGNS

1: Power semiconductor device
2: Semiconductor wafer
21: Second main side surface
22: First main side surface
23: First semiconductor layer; p-type anode layer
231: Circumferential end of the first semiconductor layer
24: Second semiconductor layer; n-type drift layer
25: Circumferential end of the wafer
26: Third semiconductor layer; highly doped n-type substrate
3: ion irradiation beam
5: lifetime control region
6: protecting layer
61: thin portion of the protecting layer
62: thick portion of the protecting layer
63: intermediate portion of the protecting layer
621: inner end of the thick portion
622: outer end of the thick portion
623: corner of the thick portion
71: first metal layer; anode electrode
72: second metal layer; cathode electrode
8: field limiting junction termination
81: floating field ring
82: portion of the second layer separating adjacent floating field rings
9: Junction termination extension (JTE)
91: JTE ring
d1: thickness of the thin portion
d2: thickness of the thick portion
d3: thickness of the intermediate portion

1-15. (canceled)

16. A power semiconductor device comprising:
a wafer having a first main side surface and a second main side surface opposite to the first main side surface and extending in a lateral direction;
a first electrode on the first main side surface to form a first contact;
a second electrode on the second main side surface to form a second contact;
an active region disposed in the wafer between the first and the second contacts and extending along a direction perpendicular to the first and second main side surfaces of the wafer;
a termination region disposed in the wafer and laterally surrounding the active region;
a first semiconductor layer of a first conductivity type disposed in the wafer adjacent the first main side surface, the first contact contacting the first semiconductor layer;
a second semiconductor layer of a second conductivity type that is different than the first conductivity type, the second semiconductor layer being disposed in the wafer in direct contact with the first semiconductor layer to form a first pn-junction;
a protecting layer on the first main side surface and covering the termination region, wherein the protecting layer covering the termination region comprises a thin portion and a thick portion laterally surrounding the thin portion, the thick portion having an inner end and an outer end laterally surrounding the inner end, the thick portion having a minimal thickness which is larger than a maximal thickness of the thin portion;
a plurality of floating field rings in the termination region adjacent to the first main side surface, wherein the plurality of floating field rings is formed below the thick portion of the protecting layer, each one of the floating field rings being a ring-shaped semiconductor region of the first conductivity type, which laterally surrounds the active region and the first semiconductor layer and which forms a second pn-junction with the second semiconductor layer, wherein the floating field rings are spaced from each other in the lateral direction and are separated from each other by the second semiconductor layer; and
a lifetime control region comprising defects and extending in the lateral direction throughout the active region and in the termination region, wherein a portion of the lifetime control region is covered by the thin portion of the protecting layer, the thick portion of the protecting layer not covering the lifetime control region.

17. The power semiconductor device according to claim 16, wherein the minimal thickness of the thick portion is at least double the maximal thickness of the thin portion.

18. The power semiconductor device according to claim 16, wherein the minimal thickness of the thick portion is at least 10 μm/α, the maximal thickness of the thin portion is less than 5 μm/α, and a is factor between 1 and 3.

19. The power semiconductor device according to claim 18, wherein the minimal thickness of the thick portion is at least at least 15 μm/α.

20. The power semiconductor device according to claim 18, wherein the maximal thickness of the thin portion is between 1 μm/α and 5 μm/α.

21. The power semiconductor device according to claim 16, wherein a concentration of defects at a predetermined depth below the first main side surface in a portion of the termination region covered by the thin portion of the protecting layer is at least a thousand times a concentration of such defects in a portion of the termination region covered by the thick portion of the protecting layer at the predetermined depth.

22. The power semiconductor device according to claim 21, wherein the concentration of defects at the predetermined depth below the first main side surface in a portion of the termination region covered by the thin portion of the protecting layer is at least a million times the concentration of such defects in the portion of the termination region covered by the thick portion of the protecting layer at the predetermined depth.

23. The power semiconductor device according to claim 16, wherein the inner end of the thick portion has at least the same distance in the lateral direction from a circumferential end of the first electrode as a circumferential end of the first semiconductor layer has from the circumferential end of the first electrode.

24. The power semiconductor device according to claim 16, wherein the inner end of the thick portion forms an edge between a side facing towards the active region and a side opposite to the wafer.

25. The power semiconductor device according to claim 24, wherein the edge is substantially vertical.

26. The power semiconductor device according to claim 16, wherein a semiconductor material in the lifetime control region comprises inert gas ions.

27. The power semiconductor device according to claim 26, wherein the semiconductor material in the lifetime control region comprises hydrogen ions or helium ions.

28. The power semiconductor device according to claim 16, wherein the protecting layer comprises a polymer material.

29. The power semiconductor device according to claim 16, wherein the protecting layer comprises a dielectric material.

30. The power semiconductor device according to claim 16, wherein the protecting layer covers the entire termination region.

31. A power semiconductor device comprising:
a wafer having a first main side surface and a second main side surface opposite to the first main side surface and extending in a lateral direction;
a first electrode on the first main side surface to form a first contact;
a second electrode on the second main side surface to form a second contact;
an active region disposed in the wafer between the first and the second contacts and extending along a direction perpendicular to the first and second main side surfaces of the wafer;
a termination region disposed in the wafer and laterally surrounding the active region;
a first semiconductor layer of a first conductivity type disposed in the wafer adjacent the first main side surface, the first contact contacting the first semiconductor layer;
a second semiconductor layer of a second conductivity type that is different than the first conductivity type, the second semiconductor layer being disposed in the wafer in direct contact with the first semiconductor layer to form a first pn-junction;
a protecting layer on the first main side surface and covering the entire termination region, wherein the protecting layer covering the termination region comprises a thin portion and a thick portion laterally surrounding the thin portion, the thick portion having an inner end and an outer end laterally surrounding the inner end, the thick portion having a minimal thickness which is at least double a maximal thickness of the thin portion;
a plurality of floating field rings in the termination region adjacent to the first main side surface, wherein the plurality of floating field rings is formed below the thick portion of the protecting layer, each one of the floating field rings being a ring-shaped semiconductor region of the first conductivity type, which laterally surrounds the active region and the first semiconductor layer and which forms a second pn-junction with the second semiconductor layer, wherein the floating field rings are spaced from each other in the lateral direction and are separated from each other by the second semiconductor layer; and
a lifetime control region comprising defects and extending in the lateral direction throughout the active region and in the termination region, wherein a portion of the lifetime control region is covered by the thin portion of the protecting layer, the thick portion of the protecting layer not covering the lifetime control region, wherein a concentration of defects at a predetermined depth below the first main side surface in a portion of the termination region covered by the thin portion of the protecting layer is at least a thousand times a concentration of such defects in a portion of the termination region covered by the thick portion of the protecting layer at the predetermined depth.

32. A method for fabricating a power semiconductor device, the method comprising:
providing a wafer having a first main side surface and a second main side surface opposite to the first main side surface and extending in a lateral direction, wherein the wafer comprises an active region extending along a direction perpendicular to the first and second main side surfaces of the wafer, a termination region laterally surrounding the active region, a first semiconductor layer of a first conductivity type; and a second semiconductor layer of a second conductivity type which is different from the first conductivity type, the second semiconductor layer being in direct contact with the first semiconductor layer to form a first pn-junction;
forming a first electrode on the first main side surface to form a first contact with the first semiconductor layer;
forming a second electrode at the second main side surface to form a second contact;
forming a protecting layer on the first main side surface such that the protecting layer covers the termination region and comprises a thin portion and a thick portion laterally surrounding the thin portion, the thick portion having an inner end and an outer end laterally surrounding the inner end, the thick portion having a minimal thickness which is larger than a maximal thickness of the thin portion; and
thereafter forming a lifetime control region in the wafer by irradiating the wafer with ions using the protecting layer as an irradiation mask, thereby forming defects at a predetermined depth in the active region and in a portion of the termination region covered by the thin portion of the protecting layer, and not in a portion of the termination region covered by the thick portion of the protecting layer at the predetermined depth.

33. The method according to claim 32, wherein forming the protecting layer comprises:
forming a first protecting layer with a first thickness, which covers an outer portion of the termination region, and
forming a second protecting layer with a second thickness on the first protecting layer, which covers the outer portion of the termination region and which is made of a same material as the first protecting layer, thereby forming the protecting layer comprising the first and the second protecting layers; and
wherein one of the first protecting layer and the second protecting layer also covers at least an inner portion of the termination region which is adjacent to the outer portion of the termination region, and the other of the first protecting layer and the second protecting layer does not cover the inner portion of the protecting layer.

34. The method according to claim 32, wherein forming the protecting layer comprises:
forming a uniform protecting layer covering the entire termination region;
providing a mask on the uniform protecting layer, wherein the mask is configured to expose an outer portion of the uniform protecting layer to a different amount of light than an inner portion of the uniform protecting layer;
exposing the uniform protecting layer through the mask; and
chemically removing at least a portion of the inner portion of the uniform protecting layer.

35. The method according to claim 32, wherein the lifetime control region is formed after forming the first electrode.
